(19) United States
(12) Patent Application Publication
(10) Pub. No.: US 2025/0241059 A1
(43) Pub. Date: Jul. 24, 2025

(54) STACKED FET STRUCTURE WITH IMPROVED CELL HEIGHT

(71) Applicant: INTERNATIONAL BUSINESS MACHINES CORPORATION, Armonk, NY (US)

(72) Inventors: Sagarika Mukesh, Albany, NY (US); Ruilong Xie, Niskayuna, NY (US); Alexander Reznicek, Troy, NY (US); Tsung-Sheng Kang, Ballston Lake, NY (US)

(21) Appl. No.: 18/419,601

(22) Filed: Jan. 23, 2024

(51) Int. Cl. H01L 27/092; H01L 21/822; H01L 21/8238; H01L 23/528; H01L 29/417

(52) U.S. Cl. CPC H10D 84/856; H01L 23/5286; H10D 64/254; H10D 84/0186; H10D 84/038; H10D 88/01

(57) ABSTRACT

Embodiments of present invention provide a semiconductor structure, which includes a first FET layer having a first and a second FET with a first and a second S/D region respectively; a second FET layer having a third and a fourth FET with a third and a fourth S/D region respectively, the second FET layer being on top of the first FET layer; a first deep via extending from a top level that is at or above a top surface of the third and the fourth S/D region to a bottom level that is at or below a bottom surface of the first and the second S/D region, the first deep via having an inverted trapezoidal shape; and a second deep via extending at least from the top level to the bottom level, the second deep via having a trapezoidal shape. A method of manufacturing the same is also provided.

### BACKGROUND

The present application relates to manufacturing of semiconductor integrated circuits. More particularly, it relates to stacked field-effect-transistor structure with improved cell height and method of forming the same.

As semiconductor industry moves towards smaller node, field-effect-transistors (FETs) are aggressively scaled to fit into reduced footprint or real estate, dictated by the size of node, with increased device density. In addition to reducing footprint, FETs are stacked together, one on top of another, to double the device density. Power supply to the FETs are provided either from the frontside or from the backside of the semiconductor chip.

Generally, when power supply for both the top and the bottom FET, which are stacked together, are provided from a single source such as from a frontside of the semiconductor structure, a deep via is required to connect to both the source/drain region of the FET at the bottom and the source/drain region of the FET at the top. By the nature of processing, the deep via generally has an inverted trapezoidal shape. Based on the minimum width required at the bottom of the deep via, the expanded width at the top of the deep via may cause short to a nearby contact structure, and/or at a minimum, represent a waste of space in cell height.

### SUMMARY

Embodiments of present invention provide a semiconductor structure. The semiconductor structure includes a first field-effect-transistor (FET) layer having a first FET with a first source/drain (S/D) region and a second FET with a second S/D region; a second FET layer having a third FET with a third S/D region and a fourth FET with a fourth S/D region, the second FET layer being on top of the first FET layer; a first deep via extending at least from a top level that is at or above a top surface of the third and the fourth S/D region to a bottom level that is at or below a bottom surface of the first and the second S/D region, the first deep via having an inverted trapezoidal shape; and a second deep via extending at least from the top level to the bottom level, the second deep via having a trapezoidal shape.

In one embodiment, the first deep via is adjacent to the second deep via with no FET in-between.

In another embodiment, both the first deep via and the second deep via are between the first S/D region and the second S/D region and between the third S/D region and the fourth S/D region.

In yet another embodiment, a top portion of the first deep via is surrounded by a first dielectric liner, and a bottom portion of the second deep via is surrounded by a second dielectric liner.

In one embodiment, the second FET layer is bonded onto the first FET layer at a bonding surface, and a top surface of a second dielectric liner is co-planar with the bonding surface.

According to one embodiment, the semiconductor structure further includes a first frontside S/D contact extending horizontally from the first deep via and contacting the top surface of the third S/D region of the third FET, and a second frontside S/D contact extending horizontally from the second deep via and contacting the top surface of the fourth S/D region of the fourth FET.

According to another embodiment, the semiconductor structure further includes a first backside S/D contact contacting the bottom surface of the first S/D region of the first FET, and a second backside S/D contact extending horizontally from the second deep via and contacting the bottom surface of the second S/D region of the second FET.

In one embodiment, the first deep via further extends to a level at a bottom surface of the first and the second bottom S/D contact and is conductively connected to a backside power rail (BPR) through a backside via.

Embodiments of present invention provide a method of forming a semiconductor structure. The method includes forming a first field-effect-transistor (FET) layer on top of a substrate, the first FET layer having a first source/drain (S/D) region of a first FET and a second S/D region of a second FET; forming a second dummy via in the first FET layer, the second dummy via extending from a top surface of the first FET layer to a bottom surface of the first FET layer; bonding a second FET layer onto the top surface of the first FET layer, the second FET layer having a third S/D region of a third FET and a fourth S/D region of a fourth FET; forming a first dummy via extending into the second FET layer from a top surface thereof; etching the first dummy via from the top surface of the second FET layer to create a first deep via opening and filling the first deep via opening with a first conductive material to form a first deep via; and etching the second dummy via from the bottom surface of the first FET layer to create a second deep via opening and filling the second deep via opening with a second conductive material to form a second deep via.

In one embodiment, forming the first dummy via includes creating a first dummy via opening in at least the second FET layer, lining the first dummy via opening with a first dielectric liner, and filling the first dummy via opening with a first dielectric material.

In another embodiment, etching the first dummy via to create the first deep via opening includes etching the first dielectric material, selective to the first dielectric liner, and etching the first FET layer until the first deep via opening extends through the bottom surface of the first FET layer, wherein the first deep via opening has an inverted trapezoidal shape.

In yet another embodiment, filling the first deep via opening to form the first deep via includes forming a first seed layer in the first deep via opening in an atomic-layer-deposition (ALD) process and depositing, on top of the first seed layer, the first conductive material, thereby forming the first deep via with the inverted trapezoidal shape.

In one embodiment, forming the second dummy via includes creating a second dummy via opening extending from the top surface of the first FET layer to the bottom surface of the first FET layer, lining the second dummy via opening with a second dielectric liner, and filling the second dummy via opening with a second dielectric material.

In another embodiment, etching the second dummy via to create the second deep via opening includes etching the second dielectric material from a bottom surface of the second dummy via, selective to the second dielectric liner, and etching the second FET layer until the second deep via opening reaches a level at or above a top surface of the fourth S/D region of the fourth FET, wherein the second deep via opening has a trapezoidal shape.

In yet another embodiment, the third S/D region is directly above the first S/D region, the fourth S/D region is directly above the second S/D region, the second dummy via is between the first and second S/D regions, and the first dummy via is between the third and fourth S/D regions.

### BRIEF DESCRIPTION OF THE DRAWINGS

The present invention will be understood and appreciated more fully from the following detailed description of embodiments of present invention, taken in conjunction with accompanying drawings of which:

FIG. 1 to FIG. 13 are demonstrative illustrations of cross-sectional views of a semiconductor structure at various steps of manufacturing thereof according to embodiments of present invention; and

FIG. 14 is a demonstrative illustration of a flow-chart of a method of manufacturing a semiconductor structure according to embodiments of present invention.

It will be appreciated that for simplicity and clarity purpose, elements shown in the drawings have not necessarily been drawn to scale. Further, and if applicable, in various functional block diagrams, two connected devices and/or elements may not necessarily be illustrated as being connected. In some other instances, grouping of certain elements in a functional block diagram may be solely for the purpose of description and may not necessarily imply that they are in a single physical entity, or they are embodied in a single physical entity.

### DETAILED DESCRIPTION

In the below detailed description and the accompanying drawings, it is to be understood that various layers, structures, and regions shown in the drawings are both demonstrative and schematic illustrations thereof that are not drawn to scale. In addition, for the ease of explanation, one or more layers, structures, and regions of a type commonly used to form semiconductor devices or structures may not be explicitly shown in a given illustration or drawing. This does not imply that any layers, structures, and regions not explicitly shown are omitted from the actual semiconductor structures. Furthermore, it is to be understood that the embodiments discussed herein are not limited to the particular materials, features, and processing steps shown and described herein. In particular, with respect to semiconductor processing steps, it is to be emphasized that the descriptions provided herein are not intended to encompass all of the processing steps that may be required to form a functional semiconductor integrated circuit device. Rather, certain processing steps that are commonly used in forming semiconductor devices, such as, for example, wet cleaning and annealing steps, are purposefully not described herein for economy of description.

It is to be understood that the terms “about” or “substantially” as used herein with regard to thicknesses, widths, percentages, ranges, etc., are meant to denote being close or approximate to, but not exactly. For example, the term “about” or “substantially” as used herein implies that a small margin of error may be present such as, by way of example only, 1% or less than the stated amount. Likewise, the terms “on”, “over”, or “on top of” that are used herein to describe a positional relationship between two layers or structures are intended to be broadly construed and should not be interpreted as precluding the presence of one or more intervening layers or structures.

Moreover, although various reference numerals may be used across different drawings, the same or similar reference numbers are used throughout the drawings to denote the same or similar features, elements, or structures, and thus detailed explanations of the same or similar features, elements, or structures may not be repeated for each of the drawings for economy of description. Labelling for the same or similar elements in some drawings may be omitted as well in order not to overcrowd the drawings.

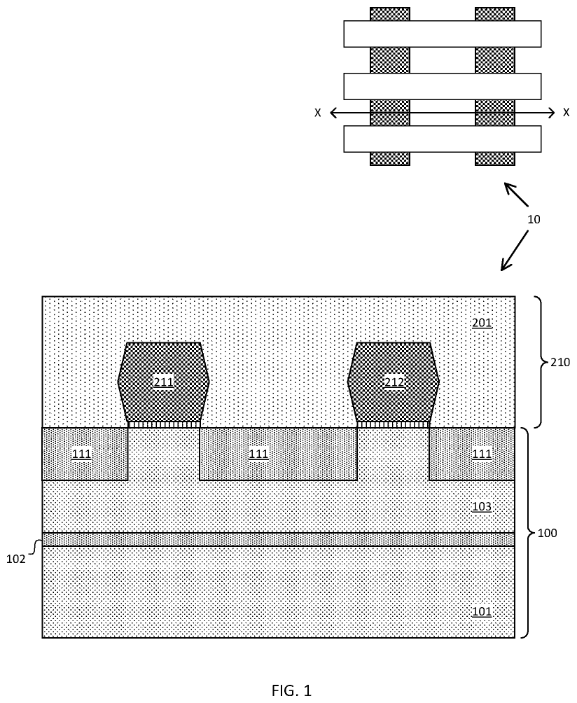

FIG. 1 is a demonstrative illustration of cross-sectional view of a semiconductor structure in a step of manufacturing thereof according to one embodiment of present invention. More specifically, FIG. 1 illustrates a cross-sectional view of a stacked field-effect-transistor (FET or simply transistor) structure, where the cross-section is made across source/drain (S/D) regions of the transistors in a widthwise direction of the gates of the transistors. A simplified top view of the structure, at the upper portion of FIG. 1, shows three unshaded horizontal bars representing gates and two shaded vertical bars representing S/D regions of the transistors. The cross-sectional view, at the lower portion of FIG. 1, is made across S/D regions of the transistors along the line X-X.

Embodiments of present invention provide forming a semiconductor structure 10 by providing or receiving a semiconductor substrate 100 and forming a first FET layer 210 on top of the semiconductor substrate 100. The first FET layer 210 may include one or more S/D regions such as a first S/D region 211 of a first FET and a second S/D region 212 of a second FET. The first and the second S/D region 211 and 212 may be embedded in and/or covered by a dielectric layer 201 and situated on top of the semiconductor substrate 100. A thin etch-stop-layer may be between the first and the second S/D region 211 and 212 and the semiconductor substrate 100.

The semiconductor substrate 100 may include a bulky silicon (Si) substrate 101, an etch-stop-layer (ESL) 102 on top of the bulky Si substrate 101, and a Si layer 103 on top of the ESL 102. The ESL 102 may be a layer of silicon-germanium (SiGe) or a layer of dielectric material such as silicon-nitride (SiN) or silicon-oxide (SiO₂). One or more shallow-trench-isolations (STIs) such as STIs 111 may be formed in the Si layer 103, in areas immediately adjacent to regions that are directly underneath the first and the second S/D region 211 and 212.

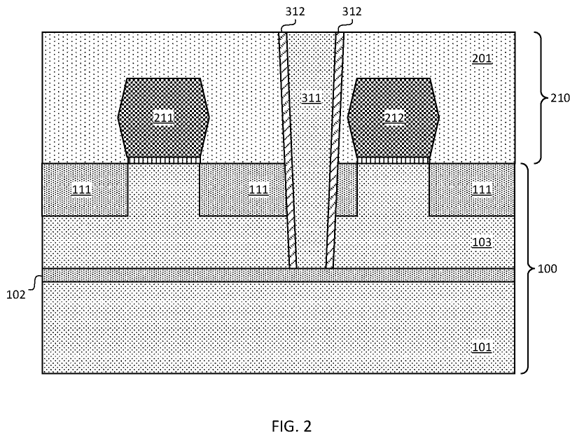

FIG. 2 is a demonstrative illustration of cross-sectional view of a semiconductor structure in a step of manufacturing thereof according to one embodiment of present invention. More particularly, following the step illustrated in FIG. 1, embodiments of present invention provide forming a second dummy via 311 (a first dummy via will be formed later) through the dielectric layer 201, between the first and the second S/D region 211 and 212 to reach at least a level that is at or below a bottom surface of the first and the second S/D region 211 and 212. For example, the second dummy via 311 may be formed from a top surface of the first FET layer 210, through the dielectric layer 201 into the STI 111 underneath thereof, then through the STI 111 into the Si layer 103 until, for example, reaching the ESL 102.

In forming the second dummy via 311, according to one embodiment, a second dummy via opening may first be created through a directional etch process such as, for example, a reactive-ion-etch (RIE) process. The second dummy via opening may extend through the dielectric layer 201, the STI 111, the Si layer 103 until the ESL 102 is exposed. By the nature of the RIE process, the second dummy via opening, and more particularly a vertical cross-section of the second dummy via opening, may have an inverted trapezoidal shape. Next, a second dielectric liner 312 (a first dielectric liner will be formed later together with a first dummy via) may be formed, for example through deposition, to line sidewalls of the second dummy via opening. In one embodiment, the second dielectric liner 312 may be a conformal liner and may be made of, for example, SiO₂. In one embodiment, the second dielectric liner 312 may be a liner of materials, other than dielectric, such as amorphous silicon (a-Si) or polysilicon (poly-Si). As is illustrated in FIG. 2, a top surface of the second dielectric liner 312 may be co-planar with a top surface of the first FET layer 210, which may be a top surface of the dielectric layer 201.

Following forming the second dielectric liner 312, a second dielectric material (a first dielectric material is used to for a first dummy via later) such as, for example, SiN, SiNCH, or SiCOH may be deposited into the second dummy via opening, thereby forming the second dummy via 311. Following the shape of the second dummy via opening, the second dummy via 311 may have an inverted trapezoidal shape. Next, a top surface of the second dummy via 311 may be planarized, for example through a chemical-mechanical-polishing (CMP) process, to be coplanar with the top surface of the second dielectric liner 312 and the dielectric layer 201, thereby preparing a top surface of the first FET layer 210 as a bonding surface which may be bonded onto a second FET layer, as being described below in more details.

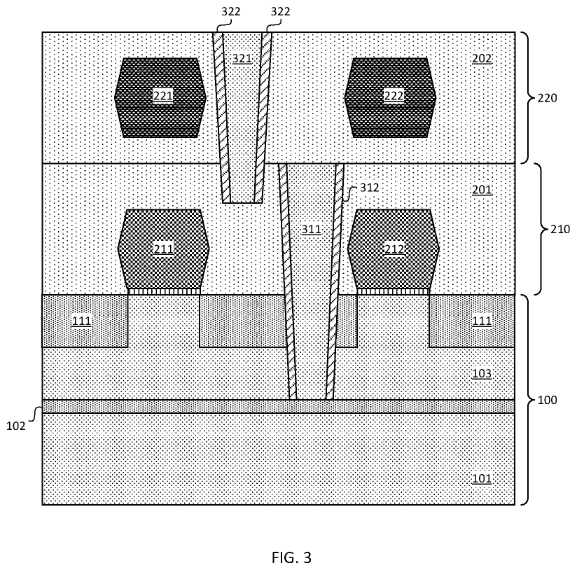

FIG. 3 is a demonstrative illustration of cross-sectional view of a semiconductor structure in a step of manufacturing thereof according to one embodiment of present invention. More particularly, following the step illustrated in FIG. 2, embodiments of present invention provide bonding a second FET layer 220 onto the first FET layer 210. After bonding, the second FET layer 220 may subsequently be formed to include one or more S/D regions of one or more FETs. For example, the second FET layer 220 may be formed to include at least a third S/D region 221 of a third FET and a fourth S/D region 222 of a fourth FET. The third S/D region 221 and the fourth S/D region 222 may be embedded in a dielectric layer 202.

In one embodiment, after bonding the second FET layer 220 on top of the first FET layer 210, the third S/D region 221 may be formed to be directly above the first S/D region 211 thereby forming a first stack of FETs, and the fourth S/D region 222 may be formed to be directly above the second S/D region 212 thereby forming a second stack of FETs. In another embodiment, the first S/D region 211 and the third S/D region 221 may be separated by the dielectric layers 201 and 202 surrounding thereof respectively. The second S/D region 212 and the fourth S/D region 222 may be similarly separated. For example, the first S/D region 211 and the third S/D region 221, and the second S/D region 212 and the fourth S/D region 222, may both be separated by about 30 nm. In comparison, the first S/D region 211 and the second S/D region 212 may be separated by about 30 nm as well.

After bonding the second FET layer 220 onto the first FET layer 210, embodiments of present invention provide forming a first dummy via 321 at least in the second FET layer 220 between the third S/D region 221 and the fourth S/D region 222. For example, in one embodiment, the first dummy via 321 may be formed from a top surface of the second FET layer 220, that is, a top surface of the dielectric layer 202, through the second FET layer 220 and formed partially into the first FET layer 210.

When forming the first dummy via 321, embodiments of present invention provide creating a first dummy via opening in the dielectric layer 202; lining the first dummy via opening with a first dielectric liner 322 of, for example, SiO₂ at sidewalls thereof, and subsequently filling the first dummy via opening with a first dielectric material of, for example, SiN, SiNCH, or SiCOH to form the first dummy via 321. Similar to the second dummy via opening, the second dielectric liner 312, and the second dummy via 311, the first dummy via opening may have an inverted trapezoidal shape because of the nature of the directional etch process such as the RIE process in creating thereof. The first dielectric liner 322 may be a conformal dielectric liner, and the first dummy via 321 may have an inverted trapezoidal shape as well, following the shape of the first dummy via opening. The first dummy via 321 may be formed to be horizontally next to the second dummy via 311 with no S/D regions of transistors in-between. Forming the first and the second dummy via 321 and 311 next to each other enables a process to form a first and a second middle-of-line (MOL) interconnect next to each other, as being described below in more details. The first MOL interconnect may have an inverted trapezoidal shape and the second MOL interconnect may have a trapezoidal shape. According to one embodiment of present invention, placing the first and the second MOL interconnect with complementary shapes next to each other may help improve the stacked FET structure by reducing a cell height thereof.

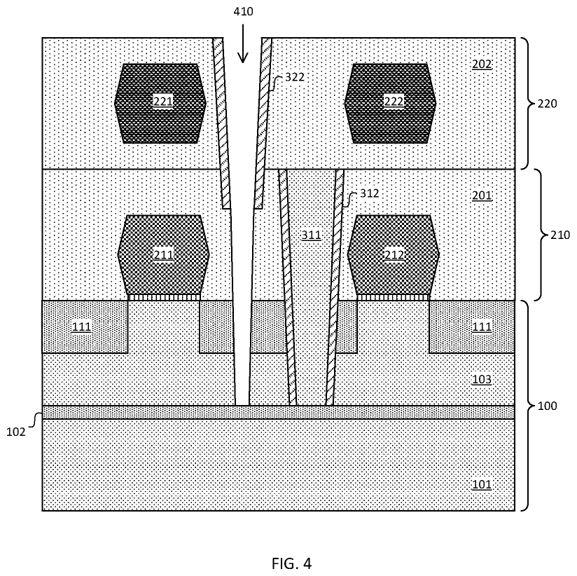

FIG. 4 is a demonstrative illustration of cross-sectional view of a semiconductor structure in a step of manufacturing thereof according to one embodiment of present invention. More particularly, following the step illustrated in FIG. 3, embodiments of present invention provide forming a first deep via opening 410 by selectively etching the first dielectric material of the first dummy via 321, relative to the surrounding first dielectric liner 322. In one embodiment, the etching may remove, completely or substantially, the first dummy via 321 surrounded by the first dielectric liner 322. However, embodiments of present invention are not limited in this aspect and, depending on specific etch conditions, a portion of the first dummy via 321 may remain (not shown) at sidewalls of the first dielectric liner 322.

After etching through the first dummy via 321, embodiments of present invention provide continuing etching the dielectric layer 202 and/or the dielectric layer 201 exposed by the removal of the first dummy via 321 in a directional and selective etch process; etching the STI 111; etching the Si layer 103 until the ESL 102 in the semiconductor substrate 100 is exposed. The resulting first deep via opening 410 may have an inverted trapezoidal shape, in a cross-section thereof. For example, in one embodiment, a width of the first deep via opening 410 at a level that is at or above a top surface of the third S/D region 221 may be, for example, 20 nm and twice as big as a width of the first deep via opening 410 at a level that is at or below a bottom surface of the first S/D region 211, which may be, for example, 10 nm.

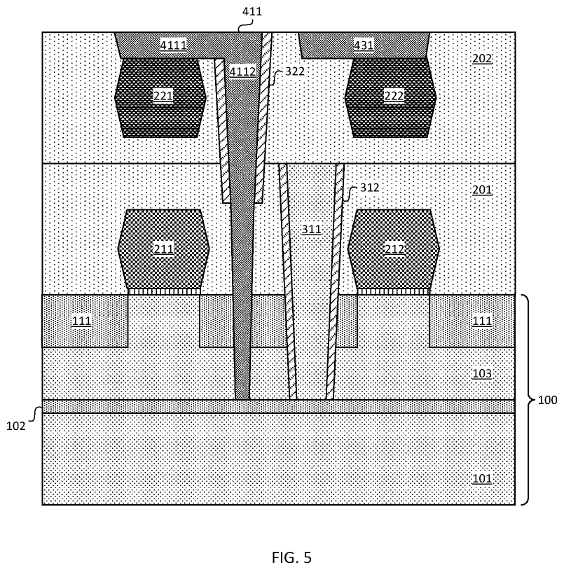

FIG. 5 is a demonstrative illustration of cross-sectional view of a semiconductor structure in a step of manufacturing thereof according to one embodiment of present invention. More particularly, following the step illustrated in FIG. 4, embodiments of present invention provide filling the first deep via opening 410 with a first conductive material such as, for example, ruthenium (Ru), cobalt (Co), tungsten (W), copper (Cu), or other suitable materials thereby forming a first deep via 4112. More specifically, the first deep via 4112 may be formed by first depositing a seed layer of, for example, Ru lining the first deep via opening 410, followed by depositing the first conductive material on top of the seed layer. The deposition process may be an atomic-layer-deposition (ALD) process, a chemical-vapor-deposition (CVD) process, and/or a physical-vapor-deposition (PVD) process, or other suitable deposition processes. The first deep via 4112 may have a depth that reaches at least a level at or below the bottom surface of the first S/D region 211 and the second S/D region 212 and in one embodiment, may reach the ESL 102.

After forming the first deep via 4112, embodiments of present invention provide forming one or more frontside S/D contacts such as, for example, a first frontside S/D contact 4111 and a second frontside S/D contact 431. The first frontside S/D contact 4111 may extend horizontally from the first deep via 4112 to and in contact with the top surface of the third S/D region 221. The first frontside S/D contact 4111 and the first deep via 4112 may together form a first middle-of-line (MOL) interconnect 411. The second frontside S/D contact 431 may be in contact with the top surface of the fourth S/D region 222 and may extend horizontally towards the third S/D region 221. The second frontside S/D contact 431 may be formed to have an overhang over the second dummy via 311 such that a second deep via may be formed later to be in contact with the second frontside S/D contact 431, as being described below in more details.

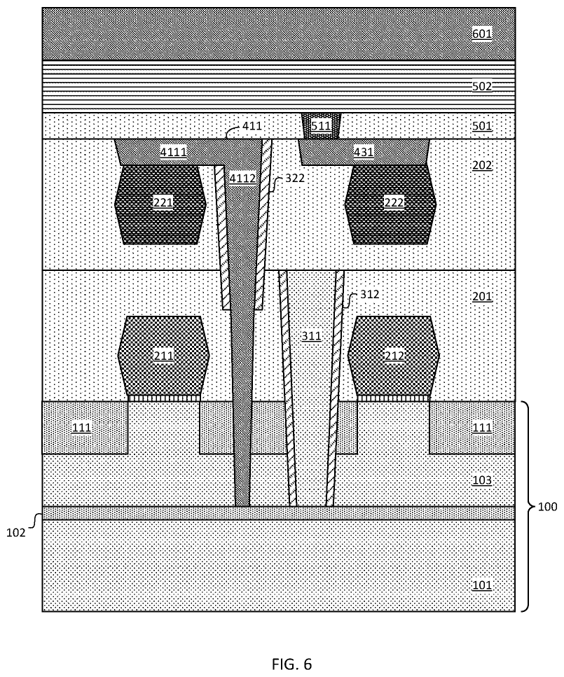

FIG. 6 is a demonstrative illustration of cross-sectional view of a semiconductor structure in a step of manufacturing thereof according to one embodiment of present invention. More particularly, following the step illustrated in FIG. 5, embodiments of present invention provide forming additional dielectric layer such as a dielectric layer 501 on top of the dielectric layer 202, and forming one or more via contacts, such as a via contact 511, in the dielectric layer 501 to be in contact with one or more of frontside S/D contacts such as to be in contact with the second frontside S/D contact 431. Embodiments of present invention further provide forming a back-end-of-line (BEOL) structure 502 on top of the dielectric layer 501 providing power supply and/or signal routing functions to the transistors underneath thereof through for example the via contact 511. A handle wafer 601 is then bonded onto the BEOL structure 502 such that the semiconductor substrate 100 may be flipped upside down for further processing from a backside thereof.

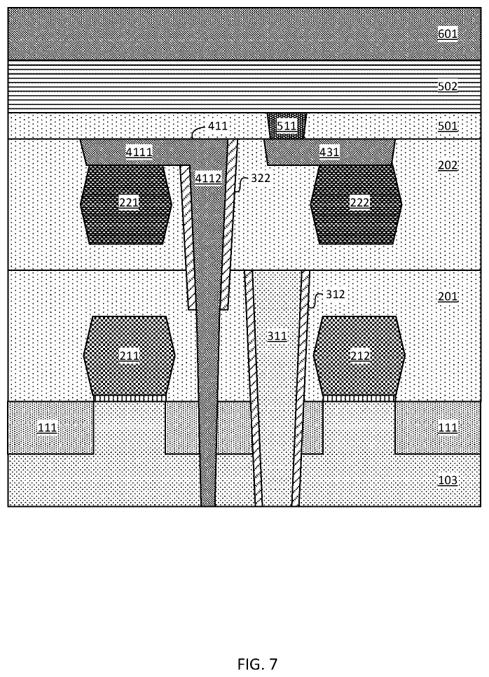

FIG. 7 is a demonstrative illustration of cross-sectional view of a semiconductor structure in a step of manufacturing thereof according to one embodiment of present invention. More particularly, following the step illustrated in FIG. 6, embodiments of present invention provide flipping the semiconductor substrate 100 upside down and removing the bulky Si substrate 101 through a grinding process, a chemical-mechanical-polishing (CMP) process, a selective wet or dry etch process and/or a combination thereof. After removing the bulky Si substrate 101, the ESL 102 may be exposed and may subsequently be removed selectively. As a result, the Si layer 103, the second dummy via 311 and the first deep via 4112 embedded in the Si layer 103 may be exposed.

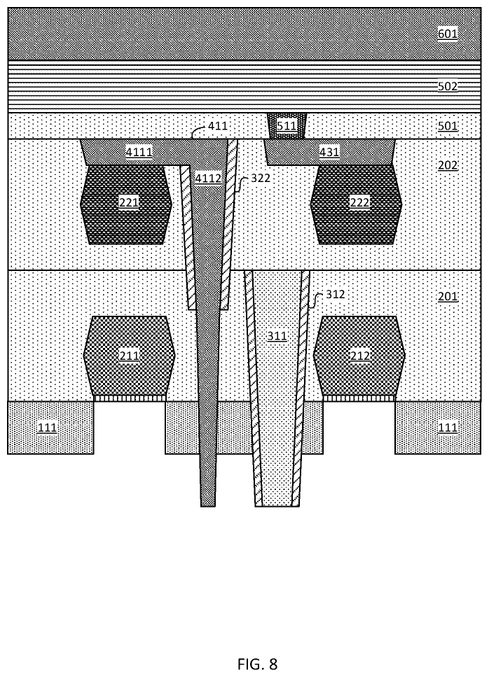

FIG. 8 is a demonstrative illustration of cross-sectional view of a semiconductor structure in a step of manufacturing thereof according to one embodiment of present invention. More particularly, following the step illustrated in FIG. 7, embodiments of present invention provide removing the Si layer 103 exposed by the removal of the ESL 102, in a selective etch process relative to the first deep via 4112, the second dummy via 311, and the one or more STIs 111. The removal of the Si layer 103 exposes bottoms of the first and the second S/D region 211 and 212, whose surfaces may be covered by a thin etch-stop-layer.

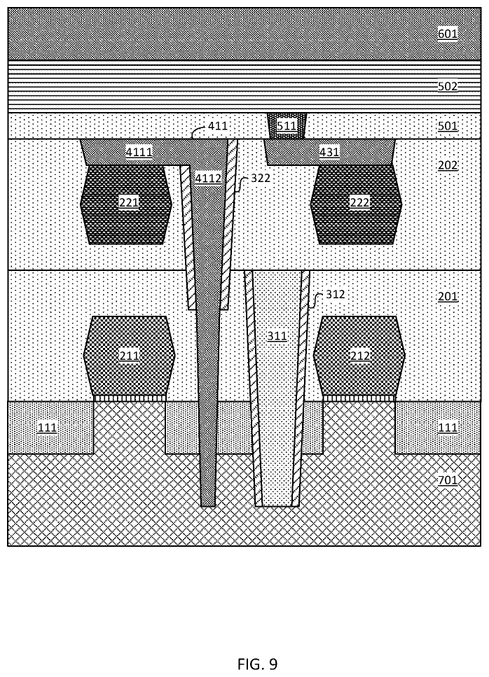

FIG. 9 is a demonstrative illustration of cross-sectional view of a semiconductor structure in a step of manufacturing thereof according to one embodiment of present invention. More particularly, following the step illustrated in FIG. 8, embodiments of present invention provide forming a backside interlevel dielectric (BILD) layer 701, for example through a deposition process such as an ALD process, a CVD process, and/or a PVD process. The BILD layer 701 may cover the bottoms of the first and the second S/D region 211 and 212, the first deep via 4112, the second dummy via 311, and the STIs 111. A CMP process may subsequently be applied to planarize a top surface of the BILD layer 701.

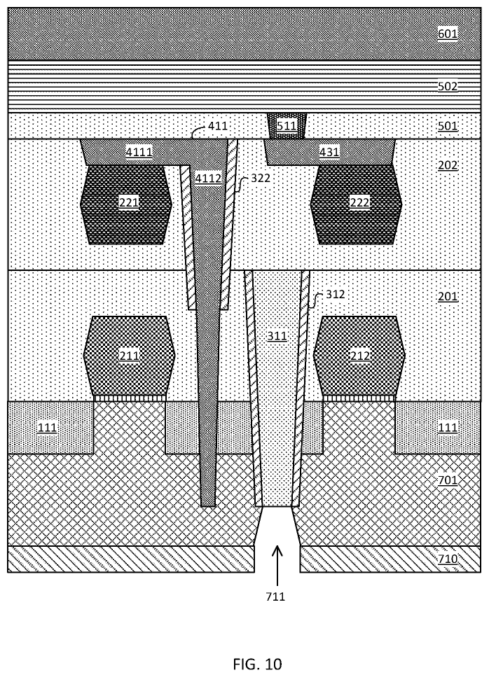

FIG. 10 is a demonstrative illustration of cross-sectional view of a semiconductor structure in a step of manufacturing thereof according to one embodiment of present invention. More particularly, following the step illustrated in FIG. 9, embodiments of present invention provide forming a hard mask 710 on top of the BILD layer 701. The hard mask 710 may have an opening that is substantially aligned with, and may be slightly larger than, the second dummy via 311. The pattern of the hard mask 710 is then transferred onto the BILD layer 701 through a selective etch process, such as a RIE process, to create an opening 711 in the BILD layer 701. The opening 711 may expose a bottom surface of the second dummy via 311.

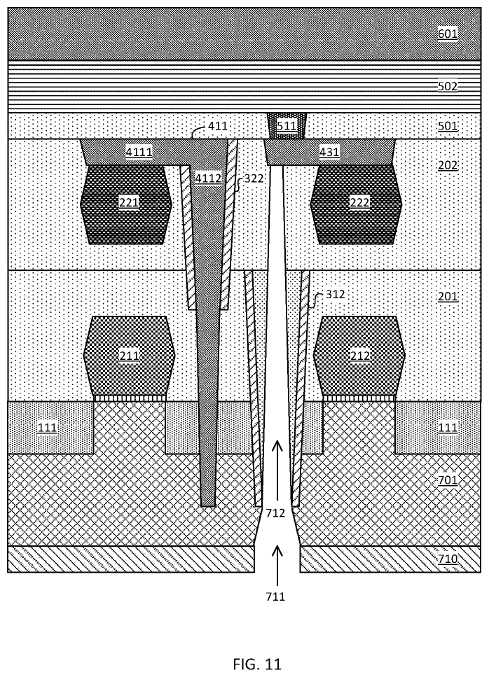

FIG. 11 is a demonstrative illustration of cross-sectional view of a semiconductor structure in a step of manufacturing thereof according to one embodiment of present invention. More particularly, following the step illustrated in FIG. 10, embodiments of present invention provide etching the second dummy via 311 through the opening 711, from the backside of the semiconductor structure 10 and in a directional and selective etch process, such as a RIE process, that is selective to the second dielectric liner 312. The etch may create a second deep via opening 712 that extends through the second dummy via 311 and through the dielectric layer 202 until the second frontside S/D contact 431 is exposed. By the process of the directional etch, the second deep via opening 712 may have a trapezoidal shape having a smaller opening at the top and a larger opening at the bottom. Unlike etching through the first dummy via 321 in creating the first deep via opening 410, due to the inverted trapezoidal shape of the second dummy via 311, portions of the second dummy via 311 may remain and surround the second deep via opening 712. In the meantime, the opening at the bottom of the second deep via opening 712 may be self-aligned to the second dielectric liner 312, which defines the beginning or opening size of the second deep via opening 712.

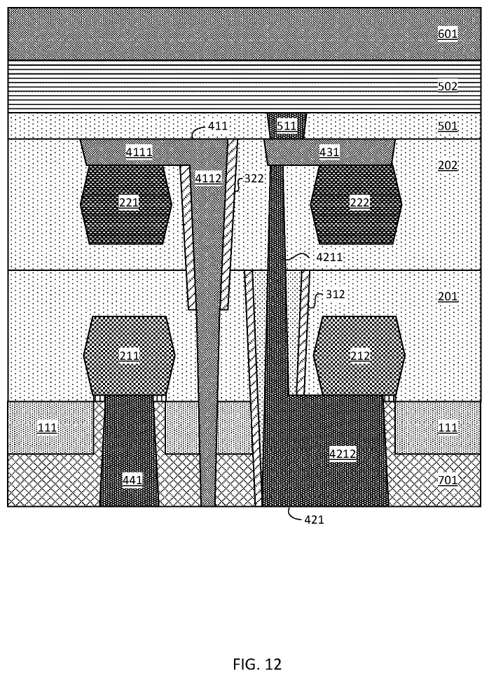

FIG. 12 is a demonstrative illustration of cross-sectional view of a semiconductor structure in a step of manufacturing thereof according to one embodiment of present invention. More particularly, following the step illustrated in FIG. 11, embodiments of present invention provide filling the second deep via opening 712 with a second conductive material to form a second deep via 4211. The second conductive material forming the second deep via 4211 may be a same material as the first conductive material forming the first deep via 4112 such as Ru, Co, W, Cu, or other suitable materials. Similar to forming the first deep via 4112, the second deep via 4211 may be formed by first depositing a seed layer of, for example, Ru lining the second deep via opening 712, followed by depositing the second conductive material. The deposition process may be an ALD process, a CVD process, a PVD process, or other suitable deposition processes currently existing or future developed.

As is illustrated in FIG. 12, the first deep via 4112 and the second deep via 4211 may be formed adjacent to each other with no S/D regions in-between. The inverted trapezoidal shape of the first deep via 4112 and the trapezoidal shape of the second deep via 4211 complement each other which helps improve, i.e., reduce the cell height of the stacked FET structure. For example, in one embodiment, a width at a top surface of the first deep via 4112 may be about two or more times bigger than a width at a bottom surface of the first deep via 4112 while a width at a top surface of the second deep via 4211 may be about equal to or less than half of a width at a bottom surface of the second deep via 4211. The top surfaces of the first and the second deep via 4112 and 4211 may be at or above the top surfaces of the third and the fourth S/D region 221 and 222, and the bottom surfaces of the first and the second deep via 4112 and 4211 may be at or below the bottom surfaces of the first and the second S/D region 211 and 212.

Next, a CMP process may be applied to planarize the top surface of the BILD layer 701, and additional openings may be created in the BILD layer 701 to expose the bottom surfaces of the first and the second S/D region 211 and 212, including removing the thin etch-stop-layer covering the bottom surfaces of the first and the second S/D region 211 and 212. A same or different conductive material may be used to fill the additional openings thereby forming one or more backside S/D contacts such as a first backside S/D contact 441 and a second backside S/D contact 4212. In one embodiment, the second backside S/D contact 4212 may be merged with the second deep via 4211 and may together form a second MOL interconnect 421.

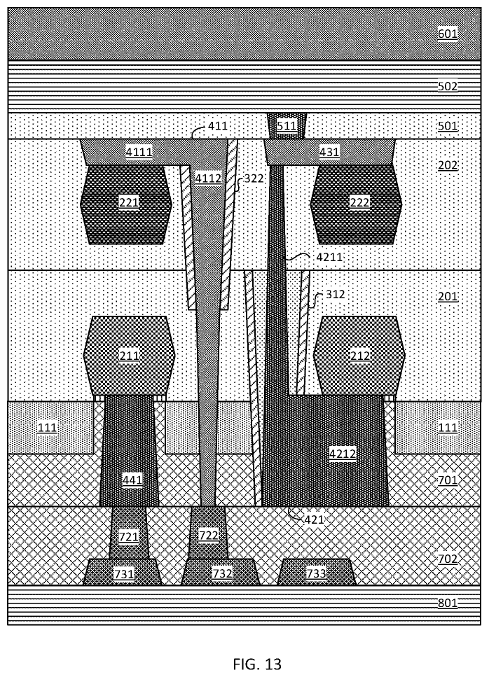

FIG. 13 is a demonstrative illustration of cross-sectional view of a semiconductor structure in a step of manufacturing thereof according to one embodiment of present invention. More particularly, following the step illustrated in FIG. 12, embodiments of present invention provide forming an additional BILD layer 702 on top of the BILD layer 701; forming one or more backside via contacts such as a first backside via contact 721 and a second backside via contact 722 contacting, for example, the first backside S/D contact 441 and the first MOL interconnect 411.

Next, backside power rails (BPRs) such a first BPR 731, a second BPR 732, and a third BPR 733 may be formed to provide power supplies to transistors, such as the first, second, third and fourth transistors, through the backside via contacts. For example, the first BPR 731 may be a VSS providing power and/or signal routing, through the first backside via contact 721 and the first backside S/D contact 441, to the first S/D region 211 of the first transistor; and the second BPR 732 may be a VDD providing power and/or signal routing, through the second backside via contact 722 and the first MOL interconnect 411, to the third S/D region 221 of the third transistor. After forming the BPRs, a backside BEOL structure 801 may be formed on top of the BILD layer 702 and the first, the second, and the third BPR 731, 732, and 733.

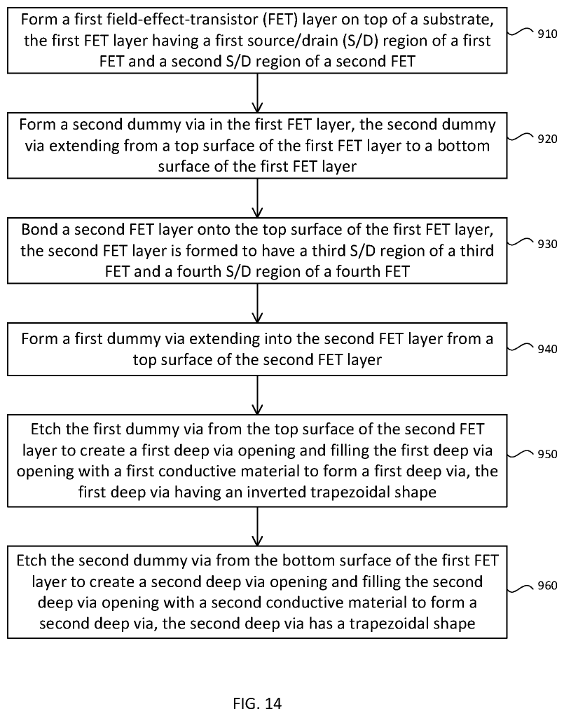

FIG. 14 is a demonstrative illustration of a flow-chart of a method of manufacturing a semiconductor structure according to embodiments of present invention. The method includes (910) forming a first field-effect-transistor (FET) layer on top of a substrate, where the first FET layer has a first S/D region of a first FET and a second S/D region of a second FET; (920) forming a second dummy via in the first FET layer, where the second dummy via extends from a top surface of the first FET layer to a bottom surface of the first FET layer; (930) bonding a second FET layer onto the top surface of the first FET layer, where the second FET layer is formed to have a third S/D region of a third FET and a fourth S/D region of a fourth FET; (940) forming a first dummy via that extends into the second FET layer from a top surface of the second FET layer; (950) etching the first dummy via from the top surface of the second FET layer to create a first deep via opening and filling the first deep via opening with a first conductive material to form a first deep via, where the first deep via has an inverted trapezoidal shape; and (960) etching the second dummy via from the bottom surface of the first FET layer to create a second deep via opening and filling the second deep via opening with a second conductive material to form a second deep via, where the second deep via has a trapezoidal shape.

It is to be understood that the exemplary methods discussed herein may be readily incorporated with other semiconductor processing flows, semiconductor devices, and integrated circuits with various analog and digital circuitry or mixed-signal circuitry. In particular, integrated circuit dies can be fabricated with various devices such as field-effect transistors, bipolar transistors, metal-oxide-semiconductor transistors, diodes, capacitors, inductors, etc. An integrated circuit in accordance with the present invention can be employed in applications, hardware, and/or electronic systems. Suitable hardware and systems for implementing the invention may include, but are not limited to, personal computers, communication networks, electronic commerce systems, portable communications devices (e.g., cell phones), solid-state media storage devices, functional circuitry, etc. Systems and hardware incorporating such integrated circuits are considered part of the embodiments described herein. Given the teachings of the invention provided herein, one of ordinary skill in the art will be able to contemplate other implementations and applications of the techniques of the invention.

Accordingly, at least portions of one or more of the semiconductor structures described herein may be implemented in integrated circuits. The resulting integrated circuit chips may be distributed by the fabricator in raw wafer form (that is, as a single wafer that has multiple unpackaged chips), as a bare die, or in a packaged form. In the latter case the chip may be mounted in a single chip package (such as a plastic carrier, with leads that are affixed to a motherboard or other high-level carrier) or in a multichip package (such as a ceramic carrier that has surface interconnections and/or buried interconnections). In any case the chip may then be integrated with other chips, discrete circuit elements, and/or other signal processing devices as part of either an intermediate product, such as a motherboard, or an end product. The end product may be any product that includes integrated circuit chips, ranging from toys and other low-end applications to advanced computer products having a display, a keyboard or other input device, and a central processor.

The descriptions of various embodiments of present invention have been presented for the purposes of illustration and they are not intended to be exhaustive and present invention are not limited to the embodiments disclosed. The terminology used herein was chosen to best explain the principles of the embodiments, practical application or technical improvement over technologies found in the marketplace, and to enable others of ordinary skill in the art to understand the embodiments disclosed herein. Many modifications, substitutions, changes, and equivalents will now occur to those of ordinary skill in the art. Such changes, modification, and/or alternative embodiments may be made without departing from the spirit of present invention and are hereby all contemplated and considered within the scope of present invention. It is, therefore, to be understood that the appended claims are intended to cover all such modifications and changes as fall within the spirit of the invention.

What is claimed is:

1. A semiconductor structure comprising:
a first field-effect-transistor (FET) layer having a first FET with a first source/drain (S/D) region and a second FET with a second S/D region;
a second FET layer having a third FET with a third S/D region and a fourth FET with a fourth S/D region, the second FET layer being on top of the first FET layer;
a first deep via extending at least from a top level that is at or above a top surface of the third and the fourth S/D region to a bottom level that is at or below a bottom surface of the first and the second S/D region, the first deep via having an inverted trapezoidal shape; and
a second deep via extending at least from the top level to the bottom level, the second deep via having a trapezoidal shape.

2. The semiconductor structure of claim 1, wherein the first deep via is adjacent to the second deep via with no FET in-between.

3. The semiconductor structure of claim 1, wherein both the first deep via and the second deep via are between the first S/D region and the second S/D region and between the third S/D region and the fourth S/D region.

4. The semiconductor structure of claim 1, wherein a top portion of the first deep via is surrounded by a first dielectric liner, and a bottom portion of the second deep via is surrounded by a second dielectric liner.

5. The semiconductor structure of claim 1, wherein the second FET layer is bonded onto the first FET layer at a bonding surface, and a top surface of a second dielectric liner is co-planar with the bonding surface.

6. The semiconductor structure of claim 1, further comprising a first frontside S/D contact extending horizontally from the first deep via and contacting the top surface of the third S/D region of the third FET, and a second frontside S/D contact extending horizontally from the second deep via and contacting the top surface of the fourth S/D region of the fourth FET.

7. The semiconductor structure of claim 1, further comprising a first backside S/D contact contacting the bottom surface of the first S/D region of the first FET, and a second backside S/D contact extending horizontally from the second deep via and contacting the bottom surface of the second S/D region of the second FET.

8. The semiconductor structure of claim 7, wherein the first deep via further extends to a level at a bottom surface of the first and the second bottom S/D contact and is conductively connected to a backside power rail (BPR) through a backside via.

9. A method of forming a semiconductor structure comprising:
forming a first field-effect-transistor (FET) layer on top of a substrate, the first FET layer having a first source/drain (S/D) region of a first FET and a second S/D region of a second FET;
forming a second dummy via in the first FET layer, the second dummy via extending from a top surface of the first FET layer to a bottom surface of the first FET layer;
bonding a second FET layer onto the top surface of the first FET layer, the second FET layer having a third S/D region of a third FET and a fourth S/D region of a fourth FET;
forming a first dummy via extending into the second FET layer from a top surface of the second FET layer;
etching the first dummy via from the top surface of the second FET layer to create a first deep via opening and filling the first deep via opening with a first conductive material to form a first deep via; and
etching the second dummy via from the bottom surface of the first FET layer to create a second deep via opening and filling the second deep via opening with a second conductive material to form a second deep via.

10. The method of claim 9, wherein forming the first dummy via comprises creating a first dummy via opening in at least the second FET layer, lining the first dummy via opening with a first dielectric liner, and filling the first dummy via opening with a first dielectric material.

11. The method of claim 10, wherein etching the first dummy via to create the first deep via opening comprises etching the first dielectric material, selective to the first dielectric liner, and etching the first FET layer until the first deep via opening extends through the bottom surface of the first FET layer, wherein the first deep via opening has an inverted trapezoidal shape.

12. The method of claim 11, wherein filling the first deep via opening to form the first deep via comprises forming a first seed layer in the first deep via opening in an atomic-layer-deposition (ALD) process and depositing, on top of the first seed layer, the first conductive material, thereby forming the first deep via with the inverted trapezoidal shape.

13. The method of claim 9, wherein forming the second dummy via comprises creating a second dummy via opening extending from the top surface of the first FET layer to the bottom surface of the first FET layer, lining the second dummy via opening with a second dielectric liner, and filling the second dummy via opening with a second dielectric material.

14. The method of claim 13, wherein etching the second dummy via to create the second deep via opening comprises etching the second dielectric material from a bottom surface of the second dummy via, selective to the second dielectric liner, and etching the second FET layer until the second deep via opening reaches a level at or above a top surface of the fourth S/D region of the fourth FET, wherein the second deep via opening has a trapezoidal shape.

15. The method of claim 9, wherein the third S/D region is directly above the first S/D region, the fourth S/D region is directly above the second S/D region, the second dummy via is between the first and second S/D regions, and the first dummy via is between the third and fourth S/D regions.

16. A semiconductor structure comprising:
a first field-effect-transistor (FET) layer having a first source/drain (S/D) region of a first FET and a second S/D region of a second FET;
a second FET layer having a third S/D region of a third FET and a fourth S/D region of a fourth FET, the third S/D region being directly above the first S/D region and the fourth S/D region being directly above the second S/D region;
a first deep via extending at least from a top level that is at or above a top surface of the third and the fourth S/D region to a bottom level that is at or below a bottom surface of the first and the second S/D region, the first deep via having an inverted trapezoidal shape; and
a second deep via extending at least from the top level to the bottom level, the second deep via having a trapezoidal shape.

17. The semiconductor structure of claim 16, wherein the first and the second deep via is between the first S/D region and the second S/D region, and between the third S/D region and the fourth S/D region.

18. The semiconductor structure of claim 16, wherein the first deep via and the second deep via are partially surrounded by a first dielectric liner and a second dielectric liner respectively.

19. The semiconductor structure of claim 16, wherein a width at a top surface of the first deep via is about twice as big as a width at a bottom surface of the first deep via.

20. The semiconductor structure of claim 16, wherein the first deep via is conductively connected to a backside power rail through a bottom via.
